(19) United States
(12) Patent Application Publication
(10) Pub. No.: US 2010/0015324 A1
(43) Pub. Date: Jan. 21, 2010

(54) VAPOR DEPOSITION SOURCE, VAPOR DEPOSITION APPARATUS, AND FILM-FORMING METHOD

(75) Inventor: Toshio NEGISHI, Chigasaki-shi (JP)

Correspondence Address: KRATZ, QUINTOS & HANSON, LLP, 1420 K Street, N.W., Suite 400, WASHINGTON, DC, 20005, US

(73) Assignee: ULVAC, Inc., Chigasaki-shi (JP)

(21) Appl. No.: 12/567,117

(22) Filed: Sep. 25, 2009

Related U.S. Application Data
(63) Continuation of application No. PCT/JP2008/054876, filed on Mar. 17, 2008.

(30) Foreign Application Priority Data
Mar. 26, 2007 (JP) 2007-078252

(51) Int. Cl. C23C 16/52; C23C 16/00

(52) U.S. Cl. 427/8; 118/726; 118/724; 118/663

(57) ABSTRACT

A vapor deposition apparatus capable of forming an organic thin film having a good film quality is provided. In the vapor deposition apparatus of the present invention, a tray is disposed in an evaporation chamber, and a feed device feeds a vapor deposition material onto the tray. The tray is placed on a mass meter, which measures the mass of the vapor deposition material disposed on the tray, and a controller compares the measured value with a reference value in order to make the feed device feed the vapor deposition material in a necessary amount. Since the vapor deposition material is replenished when needed, the vapor deposition material does not run short during the film formation, or a large amount of the vapor deposition material is not heated for a long time. Thus, the vapor deposition material does not change in quality.

This is a Continuation of International Application No. PCT/JP2008/054876 filed on Mar. 17, 2008, which claims priority of Japan Patent Document No. 2007-078252 filed on Mar. 26, 2007. The entire disclosure of the prior application is incorporated by reference herein in its entirety.

### BACKGROUND

The present invention generally relates to a technical field of an organic thin film, and more particularly, to a technology for manufacturing an organic thin film having good quality.

Organic EL elements are the types of display elements that attract the highest attention recently, and have such excellent properties as high brightness and quick response speed. In organic EL elements, light-emitting areas that emit three different colors of red, green and blue are disposed on a glass substrate. The light-emitting area is formed by stacking an anode electrode film, a hole injection layer, a hole transport layer, a light-emitting layer, an electron transport layer, an electron injection layer and a cathode electrode film in this order, and forms color of red, green or blue by a color-forming agent added in the light-emitting layer.

The hole transport layer, the light-emitting layer, the electron transport layer or the like are generally constituted of organic materials; and for forming these films of an organic material, a vapor deposition apparatus is widely used.

In FIG. 4, reference numeral 203 denotes a vapor deposition apparatus of a conventional technique, in which a vapor deposition container 212 is disposed inside a vacuum chamber 211. The vapor deposition container 212 has a container main body 221, and the upper portion of the container main body 221 is covered with a cover portion 222 having one or plural ejection ports 224 formed therein.

Inside the vapor deposition container 212, a powdery organic vapor deposition material 200 is disposed.

To the side and bottom of the vapor deposition container 212, a heater 223 is disposed; and, when the inside of the vacuum chamber 211 is evacuated to a vacuum state, and the heater 223 generates heat, then the temperature of the vapor deposition container 212 rises to heat the organic vapor deposition material 200 in the vapor deposition container 212.

When the organic vapor deposition material 200 is heated to a temperature of its evaporating temperature or more, the vapor of the organic material fills inside the vapor deposition container 212, and is ejected from the ejection port 224 into the vacuum chamber 211.

Above the ejection port 224, a substrate transfer device 214 is disposed; and when a holder 210 holds a substrate 205 and a substrate transfer device 214 is operated, the substrate 205 passes a position just above the ejection port 224, and the vapor of the organic material ejected from the ejection port 224 reaches the surface of the substrate 205 in order to form an organic thin film such as the hole injection layer or the hole transport layer.

When the substrates 205 pass one-by-one above the ejection port 224 while the vapor of the organic material is ejected, it becomes possible to successively form an organic thin film for the plural substrates 205.

See, Japanese Patent Document JP-A 2003-96557.

### SUMMARY OF THE INVENTION

In order to form a film for plural substrates 205 as described above, however, it is necessary to dispose a large amount of organic vapor deposition material 200 in the vapor deposition container 212. In actual production fields, a film deposition treatment is continuously performed for 120 hours or more while heating the vapor deposition material at 350° C. to 450° C.; and therefore, the organic vapor deposition material 200 in the vapor deposition container 212 is exposed to a high temperature for a long time, and changes in quality as the result of a reaction with moisture in the vapor deposition container, or decomposes due to the heating. Thus, the organic vapor deposition material 200 deteriorates as compared to that in the initiation condition of the heating.

The deterioration of the organic vapor deposition material 200 is prevented by increasing the feeding frequency and decreasing the amount in single feeding, but when the amount in single feeding is small, consecutive workable time becomes short. Further, when an evaporation rate of the organic vapor deposition material 200 increases due to, for example, a problem with a heater, or when the transfer speed of the substrate 205 becomes slow, the organic vapor deposition material 200 runs short while forming a film for the substrate 205, thereby resulting in inferior goods.

In order to solve the above-mentioned problem, the present invention is a vapor deposition source including: a vapor deposition container provided with an ejection port; an evaporation chamber connected to the vapor deposition container via a connection port; a tray disposed inside the evaporation chamber; a feed device for disposing the vapor deposition material on the tray; and a mass meter to which the load of the tray is applied.

The present invention is a vapor deposition source, the feed device including: a feed chamber to which the vapor deposition material is disposed; a feed pipe connected to the feed chamber at one end and to the evaporation chamber at the other end at a position above the tray; a rotation axis inserted into the feed pipe; a helical groove formed on the side face of the rotation axis; and a rotation means for rotating the rotation axis around a central axis line.

The present invention is a vapor deposition source, further comprising a heater for heating the vapor deposition material disposed on the tray.

The present invention is a vapor deposition source, wherein the heater is a laser generator, and the laser generator is configured to be capable of irradiating a laser beam to the vapor deposition material disposed on the tray.

The present invention is a vapor deposition source, further comprising a controller connected to the mass meter and the feed device, respectively, wherein: the mass meter transmits a signal corresponding to the load of the tray to the controller; and the controller controls the rotation amount of the rotation axis in response to the signal transmitted from the mass meter.

The present invention is a vapor deposition apparatus having a vacuum chamber and a vapor deposition source, the vapor deposition source including: a vapor deposition container provided with ejection ports; an evaporation chamber connected to the vapor deposition container via a connection port; a tray disposed inside the evaporation chamber; a feed device for disposing a vapor deposition material on the tray; and a mass meter to which the load of the tray is applied, wherein the internal space of the vapor deposition container and the internal space of the vacuum chamber are connected to each other via the ejection ports.

The present invention is a film-forming method comprising the steps of: feeding a vapor deposition material from a feed device to the inside of an evaporation chamber, evaporating the vapor deposition material inside the evaporation chamber, and ejecting the vapor of the vapor deposition material from at least one ejection port connected to the evaporation chamber to the inside of a vacuum chamber, and continuously moving a plurality of substrates to pass a position just above the ejection ports while moving the substrates from a transfer source to a transfer destination, to form a thin film on the surface of respective substrates, the method further including the steps of: counting the number of the substrates passing above the ejection port, and measuring the mass of the vapor deposition material inside the evaporation chamber after the substrates in a predetermined number have passed a position above the ejection port that is the nearest to the transfer destination and before the subsequent substrate reaches a position above the ejection port that is the nearest to the transfer source; comparing the measured value to a predetermined reference value; replenishing the vapor deposition material to the evaporation chamber.

The present invention is a film-forming method, further comprising the steps of: setting a mass greater than a mass necessary for forming films for the substrates in a predetermined number as the reference value; and replenishing the vapor deposition material in the evaporation chamber so that the mass of the vapor deposition material may conform with the reference value.

The present invention is a film-forming method, further including the steps of: setting a mass greater than a mass necessary for forming films for the substrates in a predetermined number as the reference value; and replenishing the vapor deposition material when the measured value becomes not more than the reference value.

The present invention is constituted as discussed above, and the vapor deposition source of the present invention can feed the vapor deposition material by the necessary amount when needed, and, therefore, there is no tendency for the vapor deposition material to deteriorate.

By comparing an actual measured value with a reference value, an intended amount of vapor deposition material can accurately be disposed inside the evaporation chamber.

A method of irradiating a laser beam to evaporate the vapor deposition material hardly causes chemical degeneration of the vapor deposition material as compared to other heating methods (such as, resistance heating).

Organic EL materials (such as, charge transfer materials, light emitting materials, or electron transfer materials) can readily exhibit chemical degeneration due to heating; thus, the use of a laser beam for heating the vapor deposition material makes it possible to manufacture organic EL apparatuses having an organic EL material of reduced degeneration in order to give a high light emitting amount.

Since a laser beam can also evaporate polymer without chemical degeneration, then polymer thin films, which have conventionally been formed by an ink-jet method, a screen printing method or a spin coat method, can be formed by an evaporation method.

The vapor deposition source of the present invention can be operated for a long time, and since a vapor deposition material is not exposed to a high temperature for a long time, the vapor deposition material does not decompose or degenerate. A thin film having the same chemical composition as that of the vapor deposition material can be formed. The use of the vapor deposition source of the present invention for forming an organic layer of organic EL apparatuses enables organic EL apparatuses having a large light-emitting amount to be manufactured. Since the vapor deposition material does not run short during film formation, the goods that are generated are not inferior. Thin films having uniform thickness distribution are formed.

### BRIEF DESCRIPTION OF THE DRAWINGS

FIG. 1 is a perspective view for illustrating a vapor deposition apparatus of the first example of the present invention.

FIG. 2 is a schematic cross-sectional view for illustrating the inside of the vapor deposition apparatus.

FIG. 3 is a schematic cross-sectional view for illustrating a vapor deposition apparatus of the second example of the present invention.

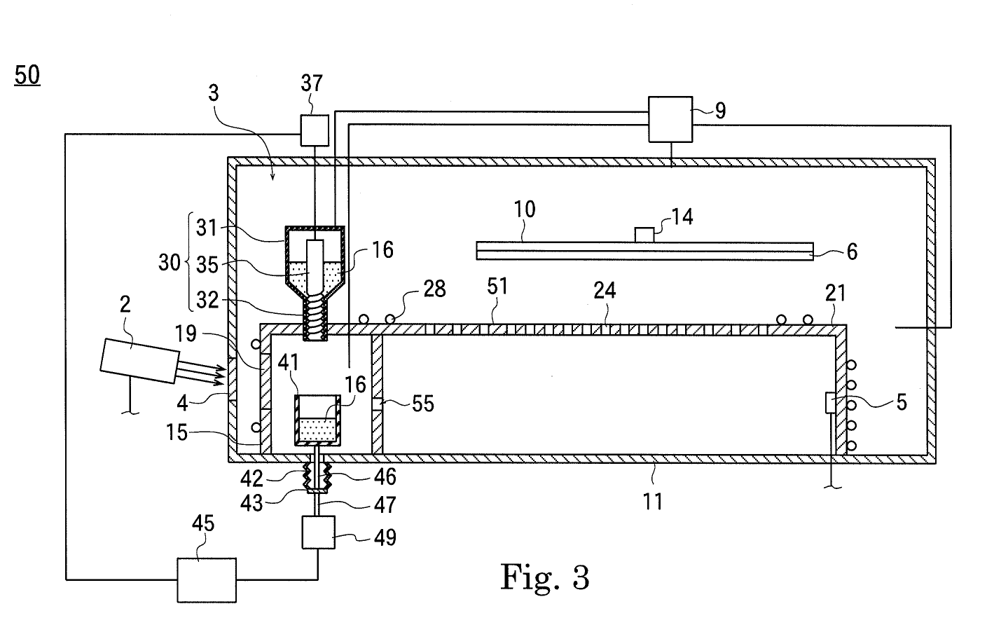

FIG. 4 is a cross-sectional view for illustrating a vapor deposition apparatus of a conventional technique.

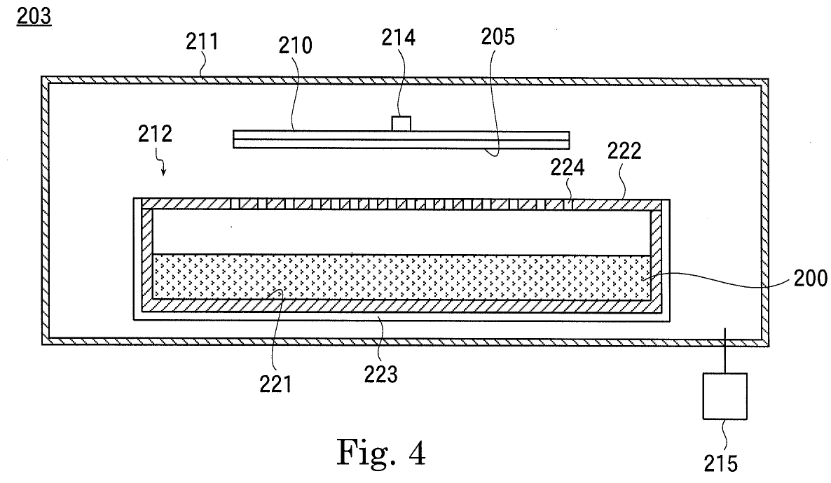

### DETAILED DESCRIPTION OF THE INVENTION

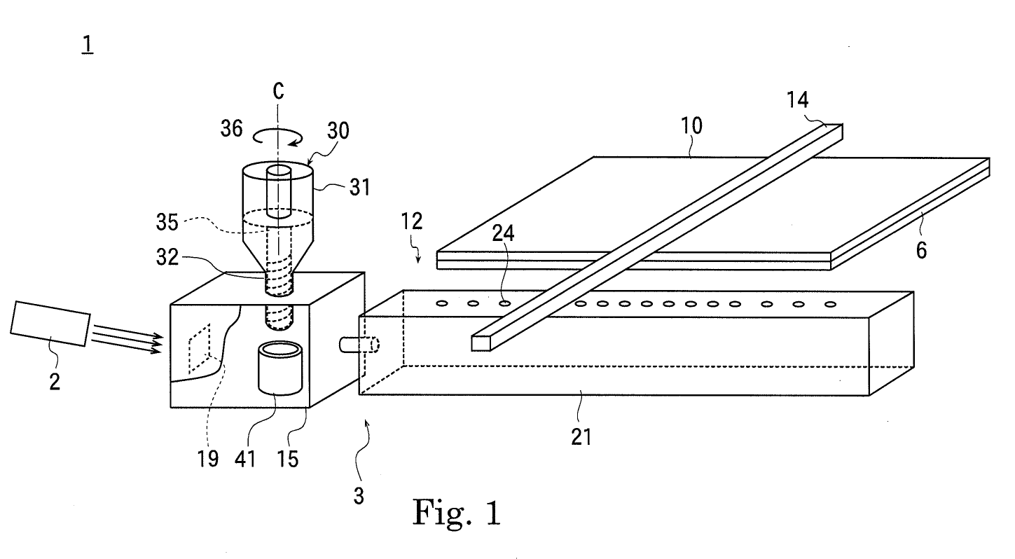

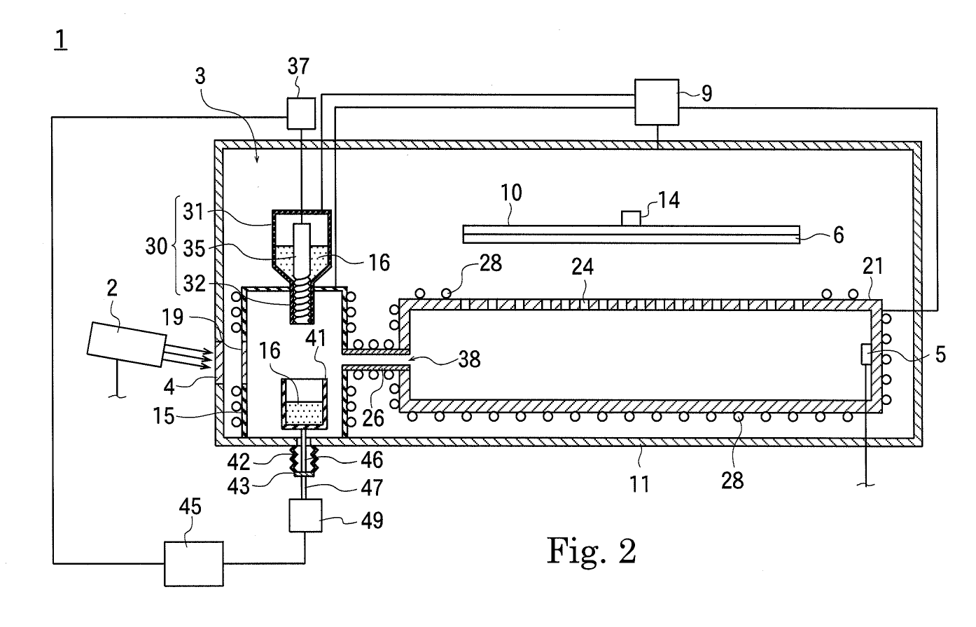

In the perspective view shown in FIG. 1 and the schematic cross-sectional view shown in FIG. 2, reference numeral 1 denotes a vapor deposition apparatus that is an embodiment of the present invention and also the first example. The vapor deposition apparatus 1 has a vacuum chamber 11 and a vapor deposition source 3 (in FIG. 1, the vacuum chamber 11 is omitted).

An evacuation system 9 is connected to the vacuum chamber 11; and by operating the evacuation system 9, the inside of the vacuum chamber 11 is evacuated.

The vapor deposition source 3 has a vapor deposition container 21, an evaporation chamber 15, a feed device 30, a tray 41, a mass meter 49, and a controller 45. The vapor deposition container 21 is disposed inside the vacuum chamber 11.

The vapor deposition container 21 has one or a plurality of ejection ports 24. As discussed later, the vapor deposition container 21 is constituted such that, when the vapor deposition material 16 fed from the feed device 30 evaporates in the evaporation chamber 15, the vapor is introduced to the inside of the vapor deposition container 21, and the vapor of the vapor deposition material is ejected from respective ejection ports 24 to the inside of the vacuum chamber 11.

Inside the vacuum chamber 11, a transfer source and a transfer destination are provided, which are not shown; and from the transfer source to the transfer destination, a substrate transfer mechanism 14 is extended. On the substrate transfer mechanism 14, a plurality of holders 10 is mounted; and on respective holders 10, a substrate 6 as a film-forming object is mounted.

The substrate 6 is transferred from the transfer source to the transfer destination one-by-one or in multiple numbers and mounted on the holder 10.

The ejection ports 24 lie beneath the transfer path, respectively on the way, along which the substrate is transferred. During the period from the arrival of the substrate edge to the edge of the ejection port 24 that is nearest to the transfer source to the moment when the substrate edge has passed through the edge of the ejection port 24 that is nearest to the transfer destination, a thin film of the vapor deposition material is formed on the substrate surface. Meanwhile, a mask may be disposed between the substrate and the ejection port 24 in order to form a thin film only in a predetermined area of the substrate surface.

Next, the vapor deposition source 3 will be discussed in detail. The feed device 30 has a feed chamber 31, a feed pipe 32, and a rotation axis 35. The feed chamber 31 is disposed above the evaporation chamber 15.

The bottom face of the feed chamber 31 is provided with an opening; and the feed pipe 32 is connected to the inside of the feed chamber 31 at one end, and is airtightly inserted into the inside of the evaporation chamber 15 from the ceiling at the other end.

In the feed chamber 31, the ceiling side has a greater diameter than the bottom side, and the side wall of the bottom portion is sloping. The vapor deposition material 16 for use in the vapor deposition apparatus 1 is powdery; and when the vapor deposition material 16 is housed in the feed chamber 31, the vapor deposition material 16 slides down the slope formed at the bottom portion in order to sink down towards the opening, which connects to the feed pipe 32.

The rotation axis 35 is inserted into the feed pipe 32 such that the top edge protrudes upward from the opening; and the vapor deposition material 16 having sunk down towards the opening accumulates around the rotation axis 35.

The portion that is above the bottom edge of the feed pipe 32 in the side surface of the rotation axis 35 has a helical groove which is formed on at least up to the position higher than the connection portion of the feed chamber 31 and the feed pipe 32; and the vapor deposition material 16 accumulated around the rotation axis 35 contacts the groove.

The convex portion between grooves of rotation axis 35 contacts the inner wall surface of the feed pipe 32, or the space between the convex portion and the inner wall surface is set to, at most, the diameter of particles of the vapor deposition material 16, so that the vapor deposition material 16 does not fall inside the evaporation chamber 15 through the opening of the bottom face of the feed chamber 31 when the rotation axis 35 is in a stationary state.

A rotation means 37 is disposed outside the vacuum chamber 11. The rotation axis 35 is connected to the rotation means 37; and when the motive power of the rotation means 37 is transmitted to the rotation axis 35, the rotation axis 35 rotates around the central axis line C without rising or descending, while maintaining the state of being inserted into the feed pipe 32.

In this embodiment, no screw thread is formed on the inner wall face of the feed pipe 32; and when the rotation axis 35 rotates in a stationary state with respect to up and down directions, the vapor deposition material 16 contacting the groove of the rotation axis 35 is extruded downward.

An opening of the bottom edge of the groove is connected to the internal space of the evaporation chamber 15; and when the vapor deposition material 16 is extruded downward, the deposition material 16 drops inside the evaporation chamber 15.

The tray 41 is disposed just under the bottom edge of the feed pipe 32 inside the evaporation chamber 15; and the fallen vapor deposition material 16 is disposed on the tray 41.

The bottom wall of the evaporation chamber 15 has a through-hole; and the top edge of an upper axis 46 is inserted into the through hole. The tray 41 is mounted on the upper axis 46.

The bottom edge of the upper axis 46 is attached to the top edge of a lower axis 47 via a support plate 43. The bottom edge of the lower axis 47 is placed on a mass meter 49. Accordingly, the tray 41 is placed on the mass meter 49 via the upper axis 46, the support plate 43 and the lower axis 47; and the load of the tray 41 and the vapor deposition material 16 on the tray 41 are applied to the mass meter 49.

In this embodiment, around the through-hole of the bottom wall of the evaporation chamber 15, one end of a bellows 42 is airtightly attached, and another end of the bellows 42 is airtightly attached to the support plate 43 around the upper axis 46 so as to isolate the internal space of the evaporation chamber 15 from an external atmosphere.

The bellows 42 is capable of expansion and contraction; and when the vapor deposition material 16 falls thereby increasing the total mass of the tray 41 and the vapor deposition material 16, the bellows 42 expands while isolating the evaporation chamber 15 from an external atmosphere in order to transmit the load of increased mass to the mass meter 49 without being blocked by the bellows 42.

The mass meter 49 and the rotation means 37, respectively, are connected to the controller 45. The mass meter 49 is, for example, a strain gage, and transmits a signal corresponding to the total load of the tray 41 and the vapor deposition material 16 on the tray 41 to the controller 45.

The mass of the tray 41 is known, and the controller 45 calculates the mass of the vapor deposition material 16 disposed on the tray 41 from the signal transmitted from the mass meter 49 and the mass of the tray 41.

The relationship between the rotation amount of the rotation axis 35 and the mass of the vapor deposition material 16 falling down to the tray 41 is known (for example, 0.01 g per one rotation); and therefore, by calculating the rotation amount of the rotation axis 35 for feeding a necessary amount of the vapor deposition material 16, and rotating the rotation axis 35 by the obtained rotation amount, it is possible to replenish the vapor deposition material 16 in a necessary amount inside the evaporation chamber 15.

The relationship between the rotation amount of the rotation axis 35 and the amount falling down to the tray 41 is not necessarily constant at all times, but, for example, when a part of the vapor deposition material 16 agglutinates to form a lump and the lump falls, an amount of the vapor deposition material 16 greater than the amount corresponding to the rotation amount falls on the tray 41. Accordingly, only the rotation of the rotation axis 35 by the rotation amount calculated from the necessary amount may cause an error.

As described above, since the controller 45 can measure the mass of the vapor deposition material 16 on the tray 41, by rotating the rotation axis 35 while measuring the mass of the vapor deposition material 16 on the tray 41, and then, stopping the rotation before the rotation is through with the rotation amount calculated from the necessary amount if a measured value reaches the necessary amount, or increasing the rotation amount if a measured value does not reach the necessary amount even after the end of the rotation amount corresponding to the necessary amount, it is possible to dispose accurately the necessary amount of the vapor deposition material 16 on the tray 41.

The evaporation chamber 15 is provided with a transparent window portion 19. In this embodiment, the evaporation chamber 15 lies inside the vacuum chamber 11, and a window portion 4 is also provided to the side wall of the vacuum chamber 11 at a position facing the window portion 19, but when at least a portion where the window portion 19 is formed is disposed outside the vacuum chamber 11 in the evaporation chamber 15, it is unnecessary to provide the window portion 4 with the vacuum chamber 11.

Outside the vacuum chamber 11, a laser generator 2, which acts as a heater is disposed; and the laser beam emitted from the laser generator 2 passes through the window portions 4 and 19 in order to irradiate the vapor deposition material 16 on the tray 41 and raise the temperature.

A connecting pipe 26 is provided between the evaporation chamber 15 and the vapor deposition container 21; and the connecting pipe 26 connects internal spaces of the evaporation chamber 15 and the vapor deposition container 21.

The ejection port 24 is provided to the ceiling of the vapor deposition container 21; and accordingly, the internal space of the evaporation chamber 15 is connected to the internal space of the vacuum chamber 11 via the connecting pipe 26, the vapor deposition container 21, and the ejection port 24.

The evacuation system 9 is connected to the vacuum chamber 11, the evaporation chamber 15, and the vapor deposition container 21, respectively. When the evacuation system 9 is operated so as to evacuate the internal space of the vacuum chamber 11, the evaporation chamber 15, and the vapor deposition container 21, until a vacuum atmosphere of a prescribed pressure is formed, the evacuation of the vacuum chamber 11 is continued, but the evacuation of the evaporation chamber 15 and the vapor deposition container 21 is stopped.

An organic material for an organic EL layer (such as a charge-transfer material, a charge-injection material, or an electron-transfer material) is disposed in the feed chamber 31 as the vapor deposition material 16; and the vapor deposition material 16 is disposed on the tray 41.

While continuing the evacuation of the vacuum chamber 11, a laser beam corresponding to an absorption wavelength of the vapor deposition material 16 is irradiated from the laser generator 2 in order to generate the vapor of the vapor deposition material 16.

In the internal space of the connecting pipe 26, since a portion (connection port) 38 having the smallest diameter is smaller than the cross-sectional figure of the evaporation chamber 15 and the vapor deposition container 21, a pressure difference occurs between the evaporation chamber 15 and the vapor deposition container 21; and the vapor filling the evaporation chamber 15 jets to the vapor deposition container 21. Here, the connecting pipe 26 has a uniform inner diameter (for example, a stainless steel pipe having an inner diameter of 1 mm), and an arbitrary portion in the connecting pipe 26 works as the connection port 38.

The vapor entering the vapor deposition container 21 through the connection port 38 is ejected into the vacuum chamber 11 through the ejection port 24 provided to the ceiling of the vapor deposition container 21 when it fills inside the vapor deposition container 21.

After the stabilization of the internal pressure of the vapor deposition container 21, and the stabilization of the vapor ejection amount from the ejection port 24, substrates 6 are continuously transferred from the transfer source to the transfer destination; and then, for respective substrates 6, a thin film of the organic material is formed during passing thereof above the ejection port 24.

By continuing the evacuation of the vacuum chamber 11 and the heating of the vapor deposition material 16, while sending plural substrates 6 from the transfer source to the transfer destination one after another, a thin film is continuously formed for each of the substrates 6.

When continuing the heating of the vapor deposition material 16 with no replenishment of the vapor deposition material 16 and forming a film for plural substrates 6, the amount of the vapor deposition material 16 on the tray 41 decreases, and the vapor deposition material 16 runs short while forming a film for one of the substrates 6, which results in the making of the substrate 6 as an inferior product.

In the present invention, before the vapor deposition material 16 runs short, the vapor deposition material 16 is replenished in a state where no substrate 6 exists above any respective ejection ports 24.

Specifically, when setting a position, just above the ejection port 24 that is nearest to the transfer source, or a position nearer the transfer source than the just-above position by a predetermined distance (as a position of starting the film-forming), and setting a position, just above the ejection port 24 that is the nearest to the transfer destination, or a position nearer the transfer destination than the just-above position by a predetermined distance (as the position of ending the film-forming), and by setting the transfer interval between a substrate 6 and a substrate 6 to be longer than the distance between the position of starting the film-forming and the position of ending the film-forming, a state (where no substrate 6 exists) occurs between the moment when the rearmost part of a preceding substrate in the transfer direction passes the position of ending the film-forming and the moment when the head of a subsequent substrate 6 in the transfer direction reaches the position of starting the film-forming, which occurs at least between the position just above the ejection port 24 on the most transfer source side and the position just above the ejection port 24 on the most transfer destination side.

When replenishing the vapor deposition material 16 while heating the vapor deposition material 16 on the tray 41, the evaporation amount increases at the moment of the replenishment to increase the ejection amount from the ejection port 24 for a short period. However, by replenishing the vapor deposition material 16 between the moment when the rearmost part of a preceding substrate in the transfer direction passes the position of ending the film-forming and the moment when the head of a subsequent substrate 6 in the transfer direction reaches the position of starting the film-forming, no substrate 6 exists above any ejection ports 24 during replenishing the vapor deposition material 16; and therefore, no unevenness occurs in the thickness distribution among the substrates 6.

A more specific explanation of the method for replenishing the vapor deposition material 16 is as follows: previously determining the number of substrates 6 to be subjected to the film-forming in one replenishment; calculating the amount of the vapor deposition material 16 necessary for forming films for the predetermined number of the substrates 6; determining a value greater than the amount as a reference value; inputting previously the number of substrates 6 to be subjected to the film-forming in one replenishment and the reference value to the controller 45.

The controller 45 counts the number of substrates 6 passing the position at which the film-forming ends, and measures the mass of the vapor deposition material 16 on the tray 41 in order to compare the measured value with the reference value, in a state where no substrate 6 exists above any ejection ports 24 and after a previously determined number of substrates 6 has passed the position at which the film-forming ends and before a subsequent substrate 6 reaches the position at which the film-forming starts.

In a first method of the present invention, the measured value is compared to the reference value in order to obtain the difference between the reference value and the measured value; and the vapor deposition material 16 equivalent to the difference is replenished before a subsequent substrate 6 reaches the position at which the film-forming starts in order to conform the mass of the vapor deposition material 16 on the tray 41 up to the reference value.

In a second method of the present invention, the measured value is compared to the reference value; and when the measured value is not less than the reference value, no replenishment is performed even when a predetermined number of substrates 6 has passed the position at which the film-forming ends in order to perform the film-forming for substrates 6 of a subsequently determined number. The measured values are compared to the reference value as to every predetermined number; and when one of the measured value becomes less than the reference value, the vapor deposition material 16 is replenished so that the measured value becomes not less than the reference value.

In both cases, since the vapor deposition material 16 is disposed in an amount necessary for forming a predetermined number of films before a subsequent substrate 6 reaches the position of starting the film-forming, vapor deposition material 16 does not run short while forming a film for a substrate 6.

Meanwhile, a measured value may be compared to the reference value as to every one of the same number, or every different number. When the comparison is performed for every different number of substrates, a reference value is calculated as to each different number; and then, a value greater than an amount necessary for a number of film-forming without the replenishment in a subsequent continuous film-forming is determined as the reference value.

Moreover, the mass of the vapor deposition material 16 on the tray 41 may be measured either after the substrate 6 has passed the position of ending the film-forming, or before the substrate 6 has passed the position of ending the film-forming in order to calculate the mass by speculation when the substrate 6 passes the position of ending the film-forming.

After all, the present invention measures the mass of the vapor deposition material 16 on the tray 41 in the state where no substrate 6 exists above any of the ejection ports 24, and, on the basis of the measured value, replenishes the vapor deposition material 16 in the state where no substrate 6 exists above any of the ejection ports 24.

The replenishment of the vapor deposition material 16 may be performed in a state where a subsequent substrate 6 is stopped nearer the transfer source than the position of starting the film-forming so as not to reach the position of starting the film-forming. After natively, if the interval for transferring the substrates 6 is long and the replenishment of the vapor deposition material 16 ends before a subsequent substrate 6 reaches the position of starting the film-forming, the vapor deposition material 16 may also be replenished while transferring the substrates 6.

The aforementioned description relates to the case where the laser generator 2 is used for heating the vapor deposition material 16, but the present invention is not limited to this. Thus, as a heating apparatus, an apparatus for heating the vapor deposition container 21 by a resistance heating element that generates heat by power supply, an apparatus for heating the vapor deposition container 21 by electromagnetic induction, an apparatus for heating the vapor deposition container 21 by irradiating infrared rays, an apparatus for heating the vapor deposition container 21 by heat conduction from a heating medium having a raised temperature, an apparatus for heating by Peltier effect, or the like may be used.

However, since the laser beam may evaporate not only inorganic materials but also organic materials (such as monomer, oligomer or polymer), and may further evaporate vapor deposition materials with a little change in the chemical composition, it is particularly preferable.

Further, since degenerated products of the vapor deposition material 16 and impurities have different absorption wavelengths from that of a target compound as the vapor deposition material 16 before the degeneration, by selecting a laser beam having a wavelength that is easily absorbed by the target compound, it is possible to selectively evaporate only the target compound and to form a thin film having a small mixed amount of degenerated products or impurities, even when a part of the vapor deposition material 16 degenerates or when impurities are mixed.

By employing a type of laser generator which may vary the wavelengths of laser beams as the laser generator 2, the wavelength of a laser beam to be emitted can be selected corresponding to the absorption wavelength of the vapor deposition material 16. Therefore, the vapor deposition apparatus 1 of the present invention can be used for forming films of various vapor deposition materials 16.

The wavelength of a laser beam is not particularly limited, but, when the vapor deposition material 16 is polymer, for example, it is from 680 nm to 10.6 μm. One example of the laser generator 2 is a CO₂ laser having an aperture of 10 to 20 μm.

In the above embodiment, an organic thin film is formed by the vapor deposition apparatus of the present invention, but the vapor deposition apparatus of the present invention is suitable for a production method of evaporating a vapor deposition material, which deteriorates due to prolonged heating, in a vacuum atmosphere and successively forming thin films on multiple film-forming objects; and a vapor deposition material whose vapor is generated in the evaporation chamber 15 is not limited to an organic compound. In short, the vapor deposition apparatus of the present invention can be used for forming inorganic thin films and thin films of composite materials, in addition to forming thin films of organic compounds.

Since the vapor of the deposition material 16 deposits by cooling, providing a heater 28 at least around the connection port 38 (connecting pipe 26) is desirable. In this embodiment, the heater 28 is also attached to the evaporation chamber 15 and the vapor deposition container 21; and, by supplying power to the heater 28 to heat the evaporation chamber 15, the vapor deposition container 21 and the connecting pipe 26 to a temperature at which no deposition of the vapor occurs, the vapor does not deposit inside the evaporation chamber 15, the vapor deposition container 21 or the connecting pipe 26.

Increasing or decreasing the evaporation amount of the vapor deposition material 16 is possible by arranging a vacuum gauge 5 in the vapor deposition container 21, connecting the vacuum gauge 5 and the laser generator 2, respectively, to the same controller 45 to which the mass meter 49 is connected, or to different controllers, obtaining the pressure inside the vapor deposition container 21 based on the signal sent from the vacuum gauge 5, and changing the irradiation time, pulse number or the like of the laser generator 2 so that the pressure becomes a targeted pressure.

In this state, the vapor amount ejected from the ejection port 24 becomes stable, but, even in a state when the laser generator 2 is controlled, the vapor ejection amount increases instantaneously at replenishing the vapor deposition material 16, and; therefore, the vapor deposition material 16 is desirably replenished in a state where no substrate 6 exists above any of the ejection ports 24.

It is also possible to arrange the evaporation chamber 15 and the feed device 30 outside the vacuum chamber 11. In such a state, the arrangement of the window portion 4 to the vacuum chamber 11 is unnecessary. No particular limitation is imposed on the number of the evaporation chambers 15 connected to one vapor deposition container 21, and a plurality of evaporation chambers 15 may be connected to one vapor deposition container 21 via the connection ports 38 to feed vapor from a plurality of evaporation chambers 15 to the vapor deposition container 21. Consequently, either vapors of the same vapor deposition materials 16 may be fed from respective evaporation chambers 15, or vapors of different vapor deposition materials 16 may be fed. By simultaneously feeding vapors of different vapor deposition materials 16, a thin film composed of two or more kinds of vapor deposition materials 16 is formed.

The aforementioned description relates to the case where the evacuation system 9 is also connected to the evaporation chamber 15 and the vapor deposition container 21, but the present invention is not limited to this. By connecting the evacuation system 9 only to the vacuum chamber 11 to evacuate the inside of the vacuum chamber to a vacuum state, it is also possible to evacuate the inside of the vapor deposition container 21 to a vacuum state via the ejection ports 24, and to further evacuate the inside of the evaporation chamber 15 to a vacuum state via the connection port 38. Also, either the evaporation chamber 15 or the vapor deposition container 21 may be connected to the evacuation system.

The aforementioned description relates to the case where the ejection port 24 is vertically pointed toward the upper direction and the substrate 6 is made to move above the ejection port 24, but the present invention is not limited to this. For example, it is also possible to make the vapor reach the surface of the substrate 6 by setting a long and narrow vapor deposition container 21 so that the long side faces the vertical downward direction, and transferring the substrates 6 supported by the holders 10 in a vertical state so as to pass the position facing the ejection ports 24.

The aforementioned description relates to the case where substrates 6 pass in a line at a position facing the ejection port 24, but the present invention is not limited to this; and the invention can also include a case where two or more transfer paths are formed and substrates 6 pass in two or more lines.

What is claimed is:

1. A vapor deposition source, comprising:
a vapor deposition container provided with an ejection port;
an evaporation chamber connected to the vapor deposition container via a connection port;
a tray disposed inside the evaporation chamber;
a feed device for disposing a vapor deposition material on the tray; and
a mass meter to which the load of the tray is applied.

2. The vapor deposition source according to claim 1, wherein the feed device includes:
a feed chamber to which the vapor deposition material is disposed;
a feed pipe connected to the feed chamber at one end and to the evaporation chamber at the other end at a position above the tray;
a rotation axis inserted into the feed pipe;
a helical groove formed on the side face of the rotation axis; and
a rotation means for rotating the rotation axis around a central axis line.

3. The vapor deposition source according to claim 1, further comprising a heater for heating the vapor deposition material disposed on the tray.

4. The vapor deposition source according to claim 3, wherein
the heater is a laser generator, and
the laser generator irradiates a laser beam to the vapor deposition material disposed on the tray.

5. The vapor deposition source according to claim 2, further comprising a controller connected to the mass meter and the feed device, respectively, wherein:
the mass meter transmits a signal corresponding to the load of the tray to the controller; and
the controller controls the rotation amount of the rotation axis in response to the signal transmitted from the mass meter.

6. A vapor deposition apparatus having a vacuum chamber and a vapor deposition source, the vapor deposition source comprising:
a vapor deposition container provided with ejection ports;
an evaporation chamber connected to the vapor deposition container via a connection port;
a tray disposed inside the evaporation chamber;
a feed device for disposing a vapor deposition material on the tray; and
a mass meter to which the load of the tray is applied, wherein
the internal space of the vapor deposition container and the internal space of the vacuum chamber are connected to each other via the ejection ports.

7. A film-forming method, comprising the steps of:
feeding a vapor deposition material from a feed device to the inside of an evaporation chamber;
evaporating the vapor deposition material inside the evaporation chamber; and
ejecting the vapor of the vapor deposition material from at least one ejection port connected to the evaporation chamber to the inside of a vacuum chamber, and continuously moving a plurality of substrates to pass a position just above the ejection ports while moving the substrates from a transfer source to a transfer destination, to form a thin film on the surface of respective substrates, the method further comprising the steps of:
counting the number of the substrates passing above the ejection port;
measuring a mass of the vapor deposition material inside the evaporation chamber, after the substrates in a predetermined number have passed a position above the ejection port that is nearest to the transfer destination, and before the subsequent substrate reaches a position above the ejection port that is nearest to the transfer source;
comparing the measured value with a predetermined reference value; and
replenishing the vapor deposition material to the evaporation chamber.

8. The film-forming method according to claim 7, further comprising the steps of:
setting a mass greater than a mass necessary for forming films for the substrates in a predetermined number as the reference value; and
replenishing the vapor deposition material in the evaporation chamber so that the mass of the vapor deposition material may conform with the reference value.

9. The film-forming method according to claim 7, further comprising the steps of:
setting a mass greater than a mass necessary for forming films for the substrates in a predetermined number as the reference value; and
replenishing the vapor deposition material when the measured value becomes not more than the reference value.
